(19) United States
(12) Patent Application Publication
(10) Pub. No.: US 2006/0216913 A1
(43) Pub. Date: Sep. 28, 2006

(54) Asymmetric bidirectional transient voltage suppressor and method of forming same

(76) Inventors: Pu-ju Kung, Taipei (TW); Chun-jen Huang, Yonghe City (TW); Lung-ching Kao, Taiei (TW); Hung-jieu Peng, Taipei (TW)

Correspondence Address: MAYER & WILLIAMS PC, 251 NORTH AVENUE WEST, 2ND FLOOR, WESTFIELD, NJ, 07090, US

(21) Appl. No.: 11/090,897

(22) Filed: Mar. 25, 2005

(51) Int. Cl. H01L 21/20; H01L 21/22; H01G 9/20

(52) U.S. Cl. 438/478; 438/549; 438/497

(57) ABSTRACT

A bi-directional transient voltage suppression device and a method of making same is provided. The method begins by providing a semiconductor substrate of a first conductivity type, and depositing a first epitaxial layer of a second conductivity type opposite the first conductivity type on the substrate. The substrate and the first epitaxial layer form a first p-n junction. A second epitaxial layer having the second conductivity type is deposited on the first epitaxial layer. The second epitaxial layer has a higher dopant concentration than the first epitaxial layer. A third layer having the first conductivity type is formed on the second epitaxial layer. The second epitaxial layer and the third layer form a second p-n junction.

### FIELD OF THE INVENTION

The present invention relates generally to transient voltage suppressors (TVS) and more particularly to an asymmetric bidirectional transient voltage suppressor.

### BACKGROUND OF THE INVENTION

Communications equipment, computers, home stereo amplifiers, televisions, and other electronic devices are increasingly manufactured using small electronic components which are very vulnerable to damage from electrical energy surges (i.e., transient over-voltages). Surge variations in power and transmission line voltages, can severely damage and/or destroy electronic devices. Moreover, these electronic devices can be very expensive to repair and replace. Therefore, a cost effective way to protect these components from power surges is needed. Devices known as transient voltage suppressors (TVS) have been developed to protect these types of equipment from such power surges or over-voltage transients. These devices, typically discrete devices similar to discrete voltage-reference diodes, are employed to suppress transients of high voltage in a power supply or the like before the transients reach and potentially damage an integrated circuit or similar structure.

One traditional device for overvoltage protection is the reversed biased p+n+Zener diode. In order to provide protection from overvoltages of either polarity, bidirectional transient voltage suppressors are often employed, which have two junctions instead of a single junction. However such bidirectional TVS's are often symmetric in that they provide the same blocking voltages for both polarities. An example of a traditional asymmetric bidirectional TVS 100 is shown schematically the cross-sectional view of FIG. 1. The device is formed on an n substrate 110. An n-type epitaxial layer 120 is formed on the upper surface of the n substrate 110. Next, p-type dopants are diffused into both sides of the substrate 110 to form p+ diffusion layers 130 and 104. Such a device contains two junctions: (1) the junction formed at the interface of p+ diffusion layer 130 and n-type epitaxial layer 120, and (2) the junction formed at the interface between the n substrate 110 and the p+ diffusion layer 104. The larger blocking voltage is supported by the junction formed at the interface of p+ diffusion layer 130 and n-type epitaxial layer 120, while the smaller blocking voltage is supported by the junction formed at the interface between the n substrate 110 and the p+ diffusion layer 104.

As shown in FIG. 2, the asymmetric bidirectional TVS of FIG. 1 is typically provided with a mesa structure on both sides of the substrate for junction termination.

A number of problems arise with respect to the asymmetric bidirectional TVS shown in FIGS. 1 and 2. First, because, diffusion layers are formed on both sides of the substrate 110, passivation must be provided on both sides to protect both junctions. The resulting double-sided bevel termination structure reduces the mechanical integrity of the device. Second, the device is relatively expensive to manufacture because the high doped substrate that is necessary is expensive because its dopant concentration must be precisely controlled.

Accordingly, it would be desirable to provide an asymmetric bidirectional TVS that overcomes the aforementioned problems.

### SUMMARY OF THE INVENTION

In accordance with the present invention, a bi-directional transient voltage suppression device and a method of making same is provided. The method begins by providing a semiconductor substrate of a first conductivity type, and depositing a first epitaxial layer of a second conductivity type opposite the first conductivity type on the substrate. The substrate and the first epitaxial layer form a first p-n junction. A second epitaxial layer having the second conductivity type is deposited on the first epitaxial layer. The second epitaxial layer has a higher dopant concentration than the first epitaxial layer. A third layer having the first conductivity type is formed on the second epitaxial layer. The second epitaxial layer and the third layer form a second p-n junction.

In accordance with one aspect of the invention, the third layer is formed by diffusion of a dopant of the first conductivity type into the second epitaxial layer.

In accordance with another aspect of the invention, the first conductivity type is p-type conductivity and the second conductivity type is n-type conductivity.

In accordance with another aspect of the invention, the substrate is a p+ substrate, the first epitaxial layer is an n-type epitaxial layer, the second epitaxial layer is an n epitaxial layer, and the third layer is a p+ layer.

In accordance with another aspect of the invention, a doping concentration of the first epitaxial layer ranges from about 1.80×10¹⁴ cm⁻³ to about 2.82×10¹⁴ cm⁻³.

In accordance with another aspect of the invention, the first epitaxial layer is grown to a thickness ranging from about 57.6 to about 70.4 microns.

In accordance with another aspect of the invention, the first conductivity type is n-type conductivity and the second conductivity type is p-type conductivity.

In accordance with another aspect of the invention, a bi-directional transient voltage suppression device is provided. The device includes a semiconductor substrate of a first conductivity type and a first epitaxial layer of a second conductivity type opposite the first conductivity type formed on the substrate. The substrate and the first epitaxial layer form a first p-n junction. A second epitaxial layer having the second conductivity type is formed on the first epitaxial layer. The second epitaxial layer has a higher dopant concentration than the first epitaxial layer. A third layer having the first conductivity type is formed on the second epitaxial layer. The second epitaxial layer and the third layer form a second p-n junction.

### BRIEF DESCRIPTION OF THE DRAWINGS

FIG. 1 shows a traditional asymmetric bidirectional TVS in a schematic, cross-sectional view.

FIG. 2 shows the asymmetric bidirectional TVS of FIG. 1 with a mesa structure.

FIG. 3, shows a schematic, cross-sectional view of an asymmetric bidirectional TVS in accordance with the present invention.

FIGS. 4A-4C show an exemplary process flow that may be used to manufacture the TVS shown in FIG. 3.

FIG. 5 shows a simulated doping profile of one particular embodiment of the present invention prior to boron diffusion.

FIG. 6 shows a simulated doping profile of the structure shown in FIG. 5 after boron diffusion.

FIG. 7 shows for the structure of FIG. 5 the simulated reverse breakdown voltage curves for both polarities.

FIG. 8 shows one alternative embodiment of the invention in which only a single epitaxial layer is employed.

FIG. 9 shows the simulated doping profile of the device depicted in FIG. 8 after the phosphorus anneal.

FIG. 10 shows the simulated doping profile of the device depicted in FIG. 8 after the boron anneal.

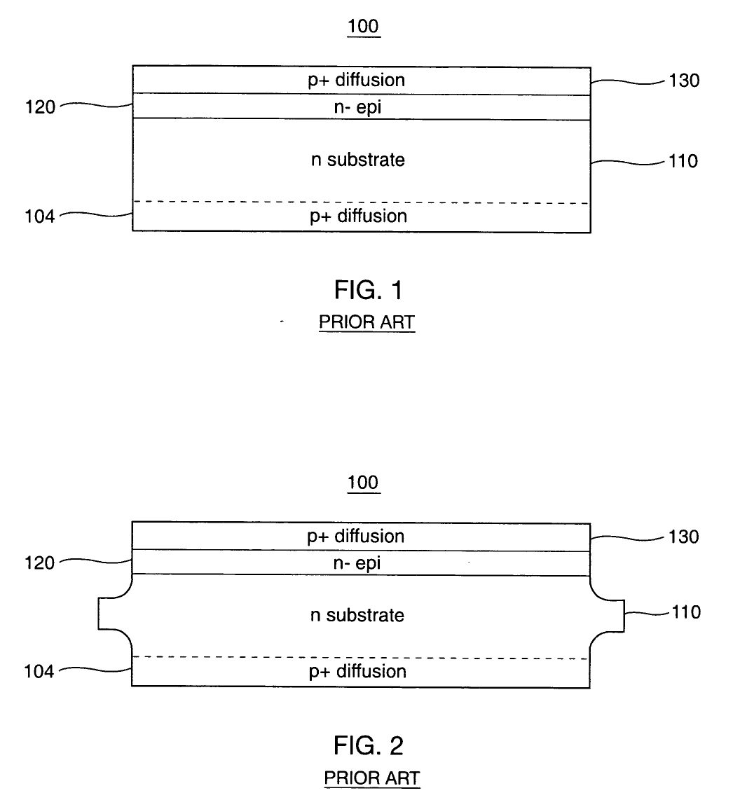

### DETAILED DESCRIPTION

Those of ordinary skill in the art will realize that the following description of the present invention is illustrative only and not in any way limiting. Other embodiments of the invention will readily suggest themselves to such skilled persons.

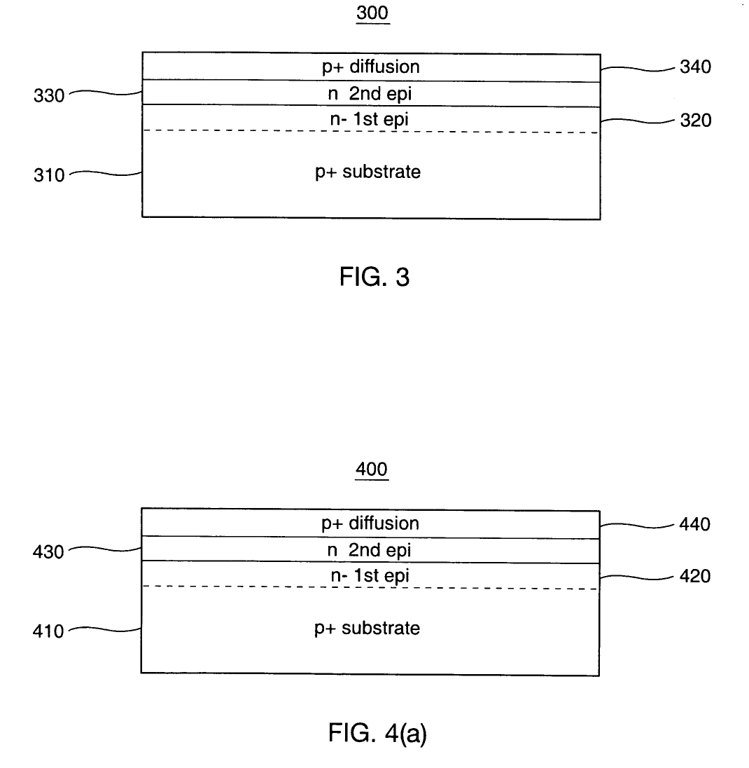

Referring now to FIG. 3, a schematic, cross-sectional view of an asymmetric bidirectional TVS 300 according to the present invention is shown. The device is formed on a p+ substrate 310. An n-type first epitaxial layer 320 is formed on the upper surface of the p+ substrate 310. An n second epitaxial layer 330 is formed on the n-type first epitaxial layer 320. Next, a p-type dopant is diffused into the n second epitaxial layer to form p+ diffusion layer 340. Such a device contains two junctions: (1) the junction formed at the interface of p+ diffusion layer 340 and n second epitaxial layer 330, and (2) the junction formed at the interface between the p+ substrate 310 and the n-type first epitaxial layer 320. The smaller blocking voltage is supported by the junction formed at the interface of p+ diffusion layer 340 and n second epitaxial layer 330, while the larger blocking voltage is supported by the junction formed at the interface between the p+ substrate 310 and the n-type first epitaxial layer 320.

The structure depicted in FIG. 3 is advantageous for a number of reasons. First, the blocking voltage supported by the junction formed at the interface between the p+ substrate 310 and the n-type first epitaxial layer 320 can be more accurately controlled because it is determined by an epitaxial growth process and not a diffusion process. Second, the two junctions can be protected by the same passivation and a single mesa structure on the top side of the device. By avoiding the need for a double-sided bevel termination structure as required in a traditional asymmetric bidirectional TVS, mechanical integrity can be preserved, thereby reducing the likelihood of breakage. Also, because a substrate with a relatively high dopant concentration is employed, the device can support the expected voltages while maintaining a better reverse surge capability.

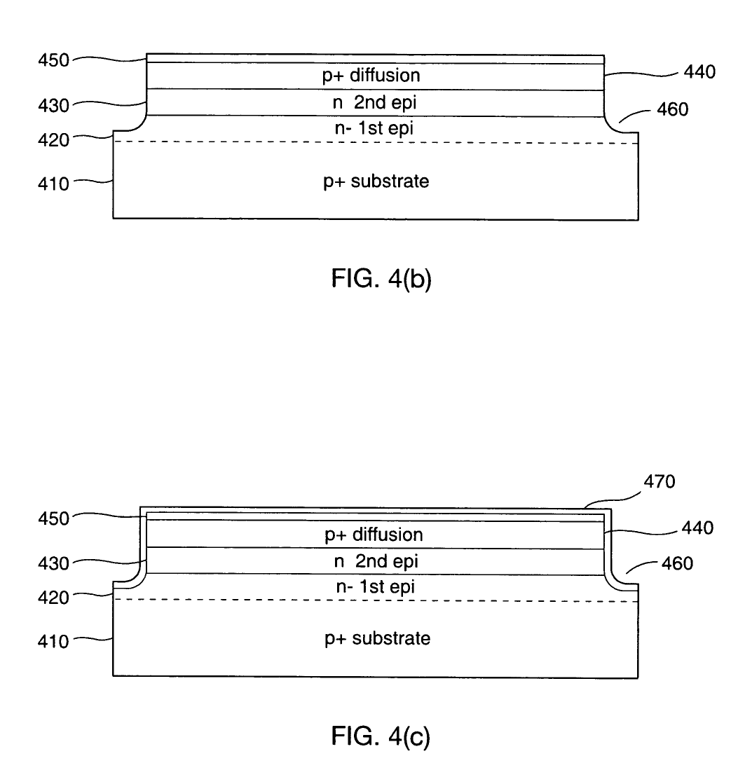

The bi-directional transient-voltage suppressors of the present invention can be manufactured using standard silicon wafer fabrication techniques. A typical process flow is shown below with reference to FIGS. 4A to 4C. Those of ordinary skill in the art will readily appreciate that the process flow disclosed herein is in no way meant to be restrictive as there are numerous alternative ways to create the bi-directional transient-voltage suppressor.

Referring now to FIG. 4A, the starting substrate material 410 for the bi-directional transient-voltage suppression device of the present invention is p-type (p+) silicon having a resistivity that is as low as possible, typically from about 0.01 to 0.002 ohm-cm⁻³. An n-type (n−) epitaxial layer 420 having a doping concentration in the range of from about 1.80×10¹⁴ to about 2.82×10¹⁴ atoms/cm³ (with lower concentrations being desired for higher breakdown voltages) is then grown to a thickness of between about 57.6 and about 70.4 microns (with lesser thicknesses being desired for higher n+ doping) on substrate 410 using conventional epitaxial growth techniques. An n epitaxial layer 430 having a doping concentration in the range of from about 4.88×10¹⁶ to about 6.46e×10¹⁶ atoms/cm³ (with lower concentration being desired for higher breakdown voltages) is then grown to a thickness of between about 26.68 and about 31.32 microns (with greater thicknesses being desired for higher breakdown voltages) on n-type epitaxial layer 420, also using conventional epitaxial growth techniques. Then, a p-type (p+) layer 440 is formed in n epitaxial layer 430, by diffusion.

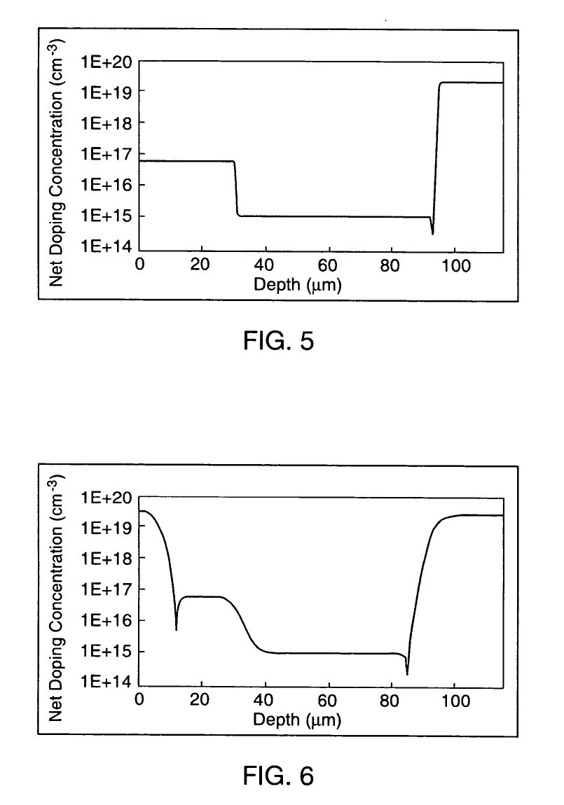

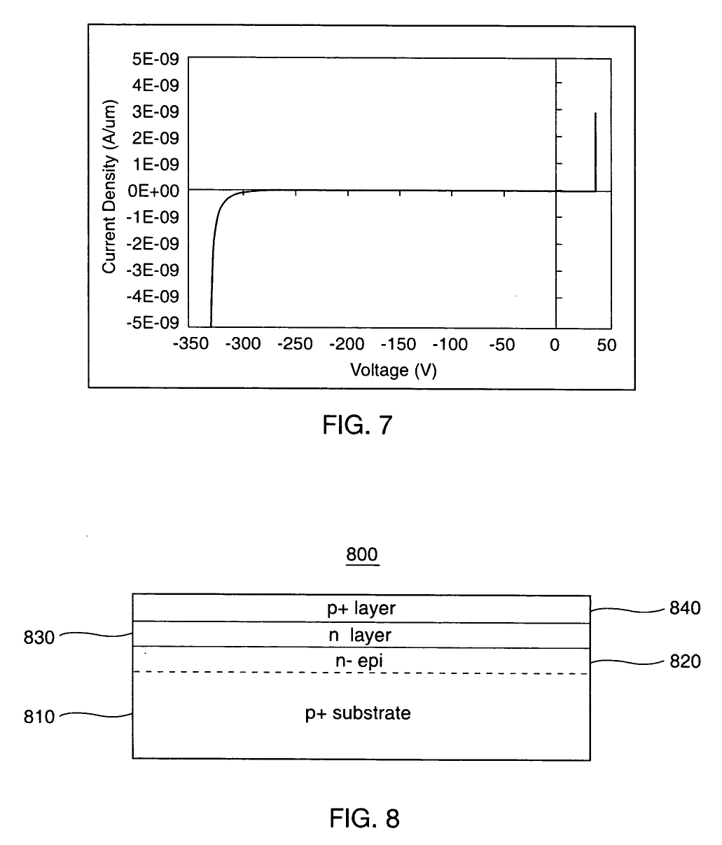

In one particular embodiment of the invention, the asymmetric bidirectional TVS is designed to operate with a breakdown voltage of 30V and 300V for the different polarities. The p+ substrate 410 has a resistivity of about 0.004 ohm-cm⁻³, the first n-type epitaxial layer 420 is 65 microns thick with a dopant concentration of 1×1015 cm⁻³. The second n epitaxial layer 430 is 30 microns thick with a dopant concentration of 5.5×10¹⁶ cm⁻³. The simulated doping profile of the structure is shown in FIG. 5 The p+ diffusion layer 440 is formed by diffusion of boron using a disk source. Drive in of the boron can be accomplished in multiple steps, if desired, for a more precise control of the breakdown voltage. The simulated doping profile of the structure after boron diffusion is shown in FIG. 6. The simulated reverse breakdown voltage curves for both polarities are shown in FIG. 7.

Referring now to FIG. 4B, a silicon nitride layer 450 is then deposited on the entire surface using conventional techniques, such as low-pressure chemical vapor deposition. A conventional photoresist masking and etching process is used to form a desired pattern in the silicon nitride layer 450. Moat trenches 460 are then formed using the patterned silicon nitride layer 450 as a mask using standard chemical etching techniques. The trenches 460 extend for a sufficient depth into the substrate (i.e., well beyond both junctions) to provide isolation and create a mesa structure. FIG. 4B shows the structure resulting after completing the silicon nitride masking and trench etching steps.

Referring now to FIG. 4C, according to an embodiment of the present invention, a thick, passifying silicon oxide layer 470, preferably about ½ micron thick is grown on the structure of FIG. 4B. Because any additional diffusion in the substrate will affect the doping profile, high temperature and long duration diffusion steps should be minimized at this point in the process. Accordingly, glass passivation in some cases may be preferable to passivation with a thermal oxide. Finally, contact openings are then formed by removing the nitride layer 450, and contacts are formed with the p+ diffusion layer 340 and p+ substrate 310 using conventional techniques (not shown).

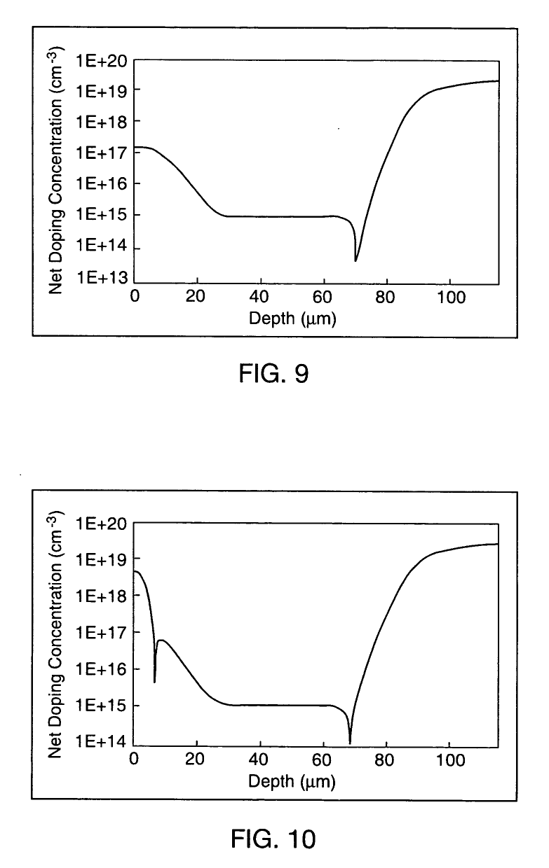

FIG. 8 shows one alternative embodiment of the invention in which only a single epitaxial layer is employed. In this case, a wafer is provided that comprises substrate 810 on which n-type epitaxial layer 820 is formed. An n layer 830 is formed on n-type epitaxial layer 820 by implantation of an appropriate n-type dopant such as phosphorus, followed by an anneal. In one particular embodiment of the invention, phosphorus is implanted at a dosage of 3×1015 cm⁻² and an energy of 80 Kev. An anneal is performed at a temperature of about 1265° C. for 15 hours. The simulated doping profile after the phosphorus anneal is shown in FIG. 9. P+ layer 840 may then be formed by the implantation of an appropriate p-type dopant such boron. In one particular embodiment of the invention, boron is implanted at a dosage of 2×1015 cm⁻² and an energy of 80 Kev. An anneal is performed at a temperature of about 1265° C. for 2 hours. The simulated doping profile after the boron anneal is shown in FIG. 10. The simulated reverse breakdown voltage curves in the resulting device for both polarities are similar to those shown in FIG. 7.

1. A method of making a bi-directional transient voltage suppression device comprising:
providing a semiconductor substrate of a first conductivity type;
depositing a first epitaxial layer of a second conductivity type opposite said first conductivity type on said substrate, said substrate and said first epitaxial layer forming a first p-n junction;
depositing a second epitaxial layer having said second conductivity type on the first epitaxial layer, said second epitaxial layer having a higher dopant concentration than said first epitaxial layer; and
forming a third layer having said first conductivity type on said second epitaxial layer, said second epitaxial layer and said third layer forming a second p-n junction.

2. The method of claim 1 wherein said third layer is formed by diffusion of a dopant of said first conductivity type into said second epitaxial layer.

3. The method of claim 1, wherein said first conductivity type is p-type conductivity and said second conductivity type is n-type conductivity.

4. The method of claim 3, wherein said substrate is a p+ substrate, wherein said first epitaxial layer is an n-type epitaxial layer, wherein said second epitaxial layer is an n epitaxial layer, wherein said third layer is a p+ layer.

5. The method of claim 1, wherein a doping concentration of the first epitaxial layer ranges from about 1.80×10¹⁴ cm⁻³ to about 2.82×10¹⁴ cm⁻³.

6. The method of claim 5, wherein the first epitaxial layer is grown to a thickness ranging from about 57.6 to about 70.4 microns.

7. The method of claim 1, wherein said first conductivity type is n-type conductivity and said second conductivity type is p-type conductivity.

8. A bi-directional transient voltage suppression device comprising:
a semiconductor substrate of a first conductivity type;
a first epitaxial layer of a second conductivity type opposite said first conductivity type formed on said substrate, said substrate and said first epitaxial layer forming a first p-n junction;
a second epitaxial layer having said second conductivity type formed on the first epitaxial layer, said second epitaxial layer having a higher dopant concentration than said first epitaxial layer; and
a third layer having said first conductivity type formed on said second epitaxial layer, said second epitaxial layer and said third layer forming a second p-n junction.

9. The bi-directional transient voltage suppression device of claim 8 wherein said third layer is formed by diffusion of a dopant of said first conductivity type into said second epitaxial layer.

10. The bi-directional transient voltage suppression device of claim 8, wherein said first conductivity type is p-type conductivity and said second conductivity type is n-type conductivity.

11. The bi-directional transient voltage suppression device of claim 4, wherein said substrate is a p+ substrate, wherein said first epitaxial layer is an n-type epitaxial layer, wherein said second epitaxial layer is an n epitaxial layer, wherein said third layer is a p+ layer.

12. The bi-directional transient voltage suppression device of claim 8, wherein a doping concentration of the first epitaxial layer ranges from about 1.80×10¹⁴ cm⁻³ to about 2.82×10¹⁴ cm⁻³.

13. The bi-directional transient voltage suppression device of claim 12, wherein the first epitaxial layer is grown to a thickness ranging from about 57.6 to about 70.4 microns.

14. The bi-directional transient voltage suppression device of claim 8, wherein said first conductivity type is n-type conductivity and said second conductivity type is p-type conductivity.
